(19) United States
(12) Patent Application Publication
(10) Pub. No.: US 2023/0273269 A1
(43) Pub. Date: Aug. 31, 2023

(54) DETERMINING STATES OF ELECTRICAL EQUIPMENT USING VARIATIONS IN DIAGNOSTIC PARAMETER PREDICTION ERROR

(71) Applicant: Hitachi Energy Switzerland AG, Baden (CH)

(72) Inventors: Luiz Cheim, Raleigh, NC (US); Roberto Zannol, Montegrotto Terme (IT); Nilanga Abeywickrama, Västerås (SE)

(21) Appl. No.: 18/023,224

(22) PCT Filed: Apr. 9, 2021
(86) PCT No.: PCT/EP2021/059352

§ 371 Date: Feb. 24, 2023

(51) Int. Cl. G01R 31/62; G01R 31/12

(52) U.S. Cl. CPC G01R 31/62; G01R 31/1227

(57) ABSTRACT

Embodiments are disclosed for determining states of electrical equipment using diagnostic parameter prediction error. A prediction error value is determined for a plurality of predicted diagnostic parameter values over a predetermined time period for at least one component of an electrical equipment. The prediction error value suppresses variations observed in behavior of the at least one component. The determined prediction error value is compared to an expected prediction error value. An indication of a state of the at least one component is selectively generated based on the comparison.

### CROSS REFERENCE TO RELATED APPLICATIONS

This application is a 35 U.S.C. § 371 national stage application of PCT International Application No. PCT/EP2021/059352 filed on Apr. 9, 2021, the disclosure and content of which is incorporated by reference herein in its entirety.

### BACKGROUND

The present disclosure relates to analysis of electrical equipment, such as high voltage transformers. In particular, the present disclosure relates to determining states of electrical equipment using diagnostic parameter prediction error.

Many diagnostic parameters for components of electrical equipment exhibit variations due to ambient and other site conditions that complicate or delay detection of underlying issues with the component difficult. For example, variations in insulation parameters of insulation bushings for high voltage transformers, such as capacitance or power factor, for example, may be indicative of bushing degradation or failure. However, these insulation parameters may be also highly susceptible to ambient conditions, such as temperature, humidity, overvoltage, or other changing environmental, electrical and/or thermal conditions in and around the electrical equipment. As a result, conventional diagnostic techniques based on such susceptible diagnostic parameters may not be able to detect a developing fault in advance or can be inaccurate in detecting a condition of a component. Therefore, such techniques may require that the transformer be taken offline to accurately detect the condition of the component.

### SUMMARY

According to some embodiments, a method includes determining, by a processor circuit, a prediction error value for a plurality of predicted diagnostic parameter values over a predetermined time period for at least one component of an electrical equipment, the prediction error value suppressing ambient variations observed in behavior of the at least one component. The method further includes comparing the determined prediction error value to an expected prediction error value. The method further includes selectively generating, by the processor circuit, an indication of a state of the at least one component based on the comparison.

According to some embodiments, the at least one component comprises an insulation component of the electrical equipment. The plurality of predicted diagnostic parameter values comprise a plurality of predicted insulation diagnostic parameter values.

According to some embodiments, the plurality of predicted insulation diagnostic parameter values comprises a plurality of at least one of predicted capacitance values, predicted capacitive current values, predicted dissipation factor values, and predicted power factor values of the at least one insulation component.

According to some embodiments, the electrical equipment comprises a transformer, and the at least one component comprises a high voltage bushing of the transformer.

According to some embodiments, the suppressed variations observed in the behavior of the at least one component comprise variations due to ambient conditions.

According to some embodiments, the variations due to ambient conditions comprise variations due to at least one of environmental conditions, noise, vibration, and special cause variation.

According to some embodiments, determining the prediction error value further comprises at least one of: predicting, by the processor circuit, at least one error value for the plurality of predicted diagnostic parameter values; determining a variation in the at least one error value due to ambient conditions observed in behavior of the at least one component; and generating the prediction error value based on the at least one error value and the determined variation.

According to some embodiments, determining the prediction error value further comprises predicting the plurality of predicted diagnostic parameter values for a plurality of respective instants of time of the predetermined time period based on obtained diagnostic parameter values. Determining the prediction error value further comprises determining a plurality of error values based on comparisons of the plurality of predicted diagnostic parameter values for the respective instants of time with a plurality of actual diagnostic parameter values obtained at the respective instants of time, wherein the prediction error value comprises an average error value for the plurality of error values.

According to some embodiments, the plurality of actual diagnostic parameter values is obtained from a parameter value data stream generated from a device associated with the at least one component.

According to some embodiments, the plurality of instants of time comprises at least 100 instants of time of the predetermined time period.

According to some embodiments, the plurality of predicted diagnostic parameter values is associated with an expected behavior of the at least one component. The prediction error value is indicative of a deviation of an observed behavior of the at least one component from the expected behavior of the at least one component.

According to some embodiments, the expected prediction error value is determined based on a comparison of a plurality of previously predicted diagnostic parameter values and a corresponding plurality of previously obtained diagnostic parameter values.

According to some embodiments, the plurality of predicted diagnostic parameter values is determined based on a plurality of determined relationships between a predefined number of diagnostic parameter values of a plurality of previously obtained diagnostic parameter values and at least one subsequent parameter value of the plurality of previously obtained diagnostic parameter values.

According to some embodiments, the plurality of previously obtained diagnostic parameter values is obtained from a different component from the at least one component.

According to some embodiments, the plurality of predicted diagnostic parameter values is determined based on at least one of a machine learning model and a statistical model.

According to some embodiments, the expected prediction error value is determined based on at least one of a machine learning model and a statistical model.

According to some embodiments, selectively generating the indication further comprises determining, by the processor circuit, whether the prediction error value meets a predetermined prediction error threshold, the predetermined prediction error threshold based on the expected prediction error value. Selectively generating the indication further comprises generating a first alert indication in response to the prediction error value meeting the predetermined prediction error threshold.

According to some embodiments, selectively generating the indication further comprises generating a second alert indication in response to the prediction error value failing to meet the predetermined prediction error threshold.

According to some embodiments, an insulation diagnostic system includes a processor circuit and a memory comprising machine-readable instructions. When executed by the processor circuit, the instructions cause the processor circuit to determine a plurality of predicted diagnostic parameter values over a predetermined time period for at least one component of an electrical equipment. The instructions further cause the processor circuit to obtain a plurality of actual diagnostic parameter values over a predetermined time period from the at least one component. The instructions further cause the processor circuit to determine a prediction error value based on the plurality of predicted diagnostic parameter values and the plurality of actual parameter values, the prediction error value suppressing ambient variations observed in behavior of the at least one component. The instructions further cause the processor circuit to compare the determined prediction error value to an expected prediction error value. The instructions further cause the processor circuit to selectively transmit an indication of a state of the at least one component to the electrical equipment based on the comparison.

According to some embodiments, the at least one component comprises an insulation component of the electrical equipment. The plurality of predicted diagnostic parameter values comprise a plurality of predicted insulation diagnostic parameter values. The plurality of actual diagnostic parameter values comprise a plurality of actual insulation diagnostic parameter values.

According to some embodiments, the plurality of predicted insulation diagnostic parameter values comprises a plurality of at least one of predicted capacitance values, predicted capacitive current values, predicted dissipation factor values, and predicted power factor values of the at least one insulation component. The plurality of actual insulation diagnostic parameter values is indicative of a plurality of at least one of actual capacitance values, actual capacitive current values, actual dissipation factors, and actual power factors of the at least one insulation component.

According to some embodiments, the suppressed variations observed in the behavior of the at least one component comprise variations due to ambient conditions.

### BRIEF DESCRIPTION OF THE DRAWINGS

The accompanying drawings, which are included to provide a further understanding of the disclosure and are incorporated in a constitute a part of this application, illustrate certain non-limiting embodiments. In the drawings:

FIGS. 1A-1C illustrate techniques for obtaining diagnostic parameter values for an insulation component, according to some embodiments;

FIGS. 2A and 2B illustrates operations for determining a state of electrical equipment based on prediction error for predicted diagnostic parameter values for the electrical equipment, according to some embodiments;

FIG. 3 illustrates operations for determining an expected prediction error value as part of the operations of FIG. 2B, according to some embodiments;

FIG. 4A is a graphical plot of historical power factor data for a transformer bushing, according to some embodiments;

FIG. 4B illustrates conversion of a time series data stream for the historical power factor data of FIG. 3 to a regression model flat table for use by a machine learning model, according to some embodiments;

FIG. 5A is a graphical plot illustrating comparisons of predicted power factors with the actual power factors over a period of time for the transformer bushing that is functioning normally, according to some embodiments;

FIG. 5B is a graphical plot illustrating power factor prediction error for the comparisons of FIG. 5A over the period of time for the normally functioning transformer bushing, according to some embodiments;

FIGS. 6A and 6B are graphical plots illustrating comparisons of predicted and actual capacitances for a transformer bushing over time and capacitance prediction error over time for the normally functioning transformer bushing, according to some embodiments;

FIG. 7 illustrates operations for determining a prediction error value as part of the operations of FIG. 2B, according to some embodiments;

FIGS. 8A and 8B are graphical plots illustrating comparisons of predicted and actual capacitances for a transformer bushing over time and capacitance prediction error over time for a transformer bushing where the actual capacitance exhibits a sudden increase, according to some embodiments;

FIGS. 9A and 9B are graphical plots illustrating comparisons of predicted and actual capacitances for a transformer bushing over time and capacitance prediction error over time for a transformer bushing where the actual capacitance exhibits a linear increase over time, according to some embodiments;

FIGS. 10A and 10B are graphical plots illustrating comparisons of predicted and actual power factors for a transformer bushing over time and power factor prediction error over time for a transformer bushing where the actual power factor exhibits a linear increase over time, according to some embodiments;

FIG. 11 illustrates operations for determining prediction error based on average predicted diagnostic parameter values and average obtained prediction error values, according to some embodiments;

FIGS. 12A and 12B illustrate calculation of average values from a time series data stream of diagnostic parameter values, according to some embodiments;

FIGS. 13A and 13B are graphical plots illustrating comparisons of plurality of average predicted and actual power factors for a transformer bushing over time and average power factor prediction error values over time for a normally functioning transformer bushing, according to some embodiments;

FIGS. 14A and 14B are graphical plots illustrating comparisons of average predicted power factors and average actual power factors for a transformer bushing over time and average power factor prediction error values over time for a transformer bushing where the actual power factor exhibits an exponential increase over time, according to some embodiments; and

FIG. 15 is a block diagram illustrating a transformer monitoring system for performing operations according to some embodiments.

### DETAILED DESCRIPTION

Embodiments will now be described more fully hereinafter with reference to the accompanying drawings, in which examples of embodiments are shown. Embodiments may, however, be embodied in many different forms and should not be construed as limited to the embodiments set forth herein. Rather, these embodiments are provided so that this disclosure will be thorough and complete, and will fully convey the scope of present disclosure to those skilled in the art. It should also be noted that these embodiments are not mutually exclusive. Components from one embodiment may be tacitly assumed to be present/used in another embodiment.

The following description presents various embodiments of the disclosed subject matter. These embodiments are presented as teaching examples and are not to be construed as limiting the scope of the disclosed subject matter. For example, certain details of the described embodiments may be modified, omitted, or expanded upon without departing from the scope of the described subject matter.

Embodiments include a method of determining a state of components of electrical equipment by detecting changes in prediction error for diagnostic parameter values of the components. For example, a prediction error value may be determined for a plurality of predicted diagnostic parameter values over a predetermined time period for at least one component of an electrical equipment. The prediction error value may also suppress ambient variations observed in behavior of the at least one component, which may result in more stable and/or reliable determinations. As used herein, the term “ambient variations” refers to variations due to ambient conditions, such as environmental temperature, noise, vibration, humidity, space/surface charge effects, component temperature, fluid pressure (e.g., a gas leak through sealing components or a housing of a transformer), vibration, electrical load, and/or special cause variation, for example.

The determined prediction error value may be compared to an expected prediction error value. Based on the comparison, an indication of a state of the component may be selectively generated.

For purposes of explanation, many of the examples described herein are directed to determining a state of a bushing or other insulation component for a high voltage transformer, using the features disclosed herein. It should be understood, however, that the disclosure and claims are not so limited and have a wide range of applicability beyond the specific examples provided herein. As used herein, the term “diagnostic parameter value” may refer to any parameter for an electrical equipment.

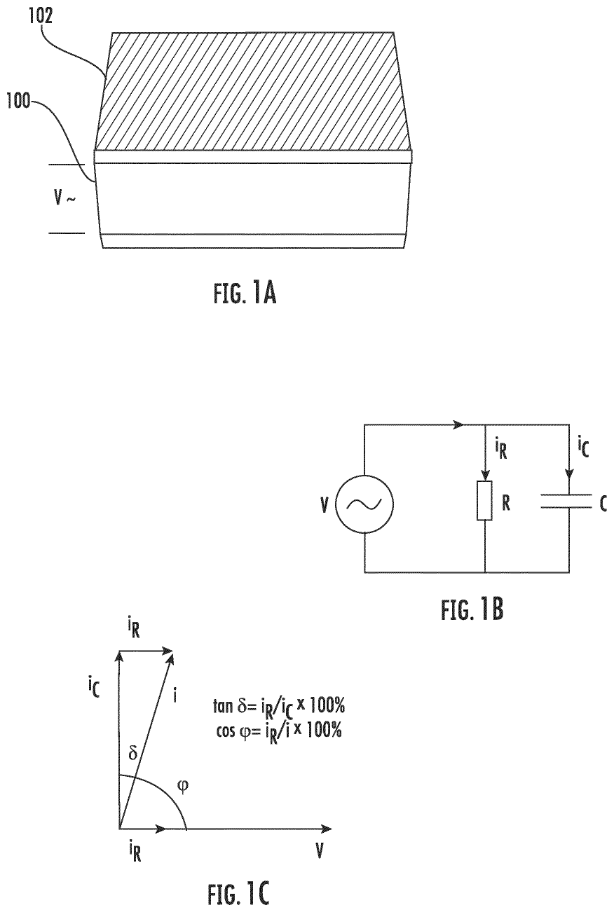

Before describing the features of the disclosed embodiments, FIGS. 1A-1C illustrate some examples of diagnostic parameters for insulation components. FIG. 1A illustrates an insulation 100 separating a pair of metallic plates 102. As shown by circuit diagram of FIG. 1B, when a voltage V is applied across the insulation 100, the total current i is divided between a natural capacitive current i_{C} component and a resistive loss current i_{R} component. For a normally functioning, e.g., undamaged, insulation 100, i_{C} should be very high relative to the loss current i_{R}. As a result, the ratio between the two parameters can be a reliable indicator of the actual condition or quality of the insulation 100. As shown by the vector diagram of FIG. 1C, a number of parameters can be measured or derived in this way. For example, the angle δ between the capacitive current i_{C} and total current i defines the dissipation factor (tan δ), with tan δ=i_{R}/i_{C}. The complementary angle ϕ between the loss current i_{R} and the total current i defines the power factor (cos ϕ), with cos ϕ=i_{R}/i. For a high-quality insulation 100 with a small δ, the dissipation factor and power factor will be very small, and will be numerically very close.

However, if the insulation 100 contains defects, such as shorted plates, punctured plates, voids, moisture, and/or particle contamination, for example, the proportion of loss current to capacitive current and total current is significantly higher. As a result, capacitance, capacitive current, dissipation factor, and power factor are all useful diagnostic parameters for determining a state of the insulation 100.

Many conventional diagnostic techniques for insulation components, such as a transformer bushing for example, involve measuring capacitance, power factor, and/or other diagnostic parameters with the transformer disconnected and offline. While it is possible to measure these diagnostic parameters while the transformer is online, this typically introduces a number of variations, such as variations due to ambient conditions (e.g., environmental conditions, temperature, noise, vibration, special cause variation, etc.), into the measured parameter values that make it difficult to obtain accurate readings, which in turn makes it difficult to detect problems in bushings or other insulation components while the transformer is online.

To address this problem, according to some embodiments, a plurality of predicted diagnostic parameter values are obtained for a predetermined time period, and a corresponding plurality of actual diagnostic parameter values are obtained for the same time period. The predicted diagnostic parameter values are compared with the actual diagnostic parameter values to obtain a prediction error value for the predicted diagnostic parameter values. This prediction error value is then compared to an expected prediction error value to accurately determine a state of the insulation component without the need to take the transformer or other electrical equipment offline.

The predicted diagnostic parameter values, prediction error value, and expected prediction error value can be obtained in a number of ways. For example, in some embodiments, the expected prediction error value can be obtained by training a machine learning model to predict diagnostic parameter values based on historical data. For example, the training may be based on determining a plurality of relationships between a predefined number of diagnostic parameter values of a plurality of previously obtained diagnostic parameter values and at least one subsequent parameter value of the plurality of previously obtained diagnostic parameter values. The previously obtained diagnostic parameter values may be obtained from the same component, or from a different component, as desired.

The trained machine learning model may then predict a plurality of diagnostic parameter values, e.g., based on the plurality of determined relationships, for an insulation component that is known to be functioning normally, and compare those predicted values to a corresponding plurality of actual diagnostic parameter values for the normally functioning insulation component. The resulting prediction error value can then be used as an expected prediction error value for future measurements of insulation components in the field.

The machine learning model can similarly obtain predicted diagnostic parameter values over a period of time for an insulation component in the field, e.g., a high voltage bushing for a transformer that is connected and online. The predicted diagnostic parameter values are compared to corresponding actual diagnostic parameter values to obtain a prediction error value, which is in turn compared to the expected prediction error value to determine the actual state of the insulation component. For normally functioning components, the prediction error value should be very close to the expected prediction error value, but for damaged or malfunctioning components, the prediction error can increase by orders of magnitude compared to the expected prediction error value, allowing for very fast and reliable detection of problems without taking the electrical equipment offline.

These and other embodiments can suppress variations observed in behavior of the component in several ways. For example, the machine learning model may account for variations in the data as part of its training process, and may suppress these variations when predicting the predicted diagnostic parameter values. Alternatively, or in addition, a moving average of multiple data points can be used to suppress these variations. For example, a prediction error value may be obtained by comparing an average predicted diagnostic parameter value for a plurality of predicted diagnostic parameter values (e.g., 100 diagnostic parameter values) to a corresponding average actual diagnostic parameter value. In another example, a plurality of error values (e.g., 100 error values) may be obtained for the respective plurality of predicted diagnostic parameter values, and a mean prediction error value can then be calculated for the plurality of error values.

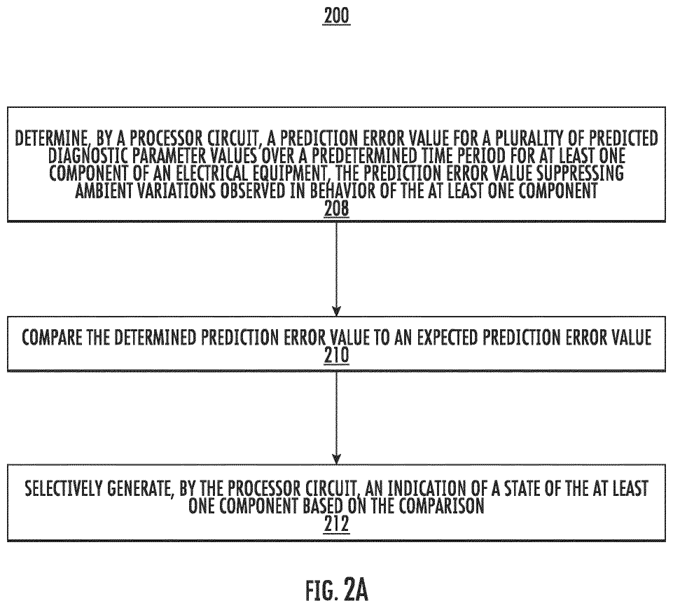

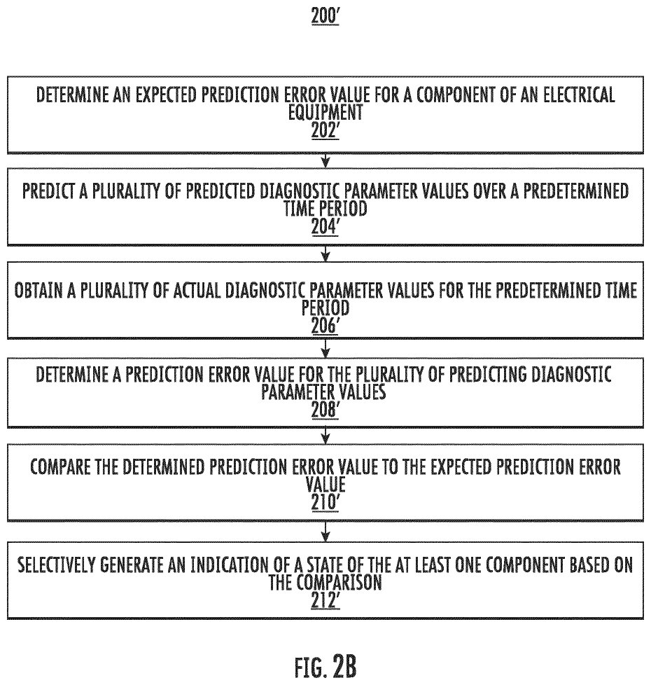

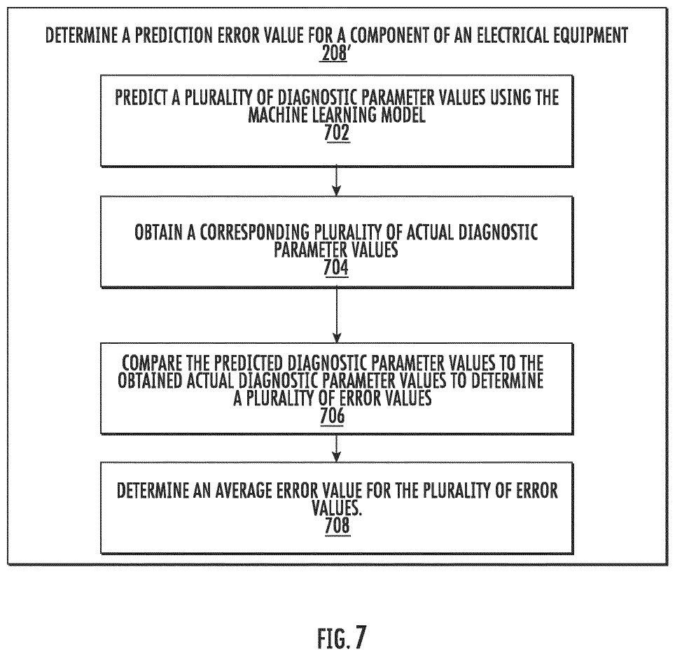

Reference is now made to FIG. 2A, which illustrates operations 200 for determining a state of electrical equipment based on prediction error for predicted diagnostic parameter values for the electrical equipment, according to some embodiments. In this example, the operations 200 include determining, by a processor circuit, a prediction error value for a plurality of predicted diagnostic parameter values over a predetermined time period for at least one component of an electrical equipment, the prediction error value suppressing ambient variations observed in behavior of the at least one component (Block 208). The operations 200 further include comparing the determined prediction error value to an expected prediction error value (Block 210). The operations 200 further include selectively generating, by the processor circuit, an indication of a state of the at least one component based on the comparison (Block 212). It should also be understood that any or all of these operations 200 can be used with other disclosed embodiments herein, such as the operations 200′of FIG. 2B described in greater detail below, for example. In addition, the any or all of these operations 200 can be used with other operations disclosed herein, including the additional operations for determining a prediction error value described in FIG. 7 below, for example.

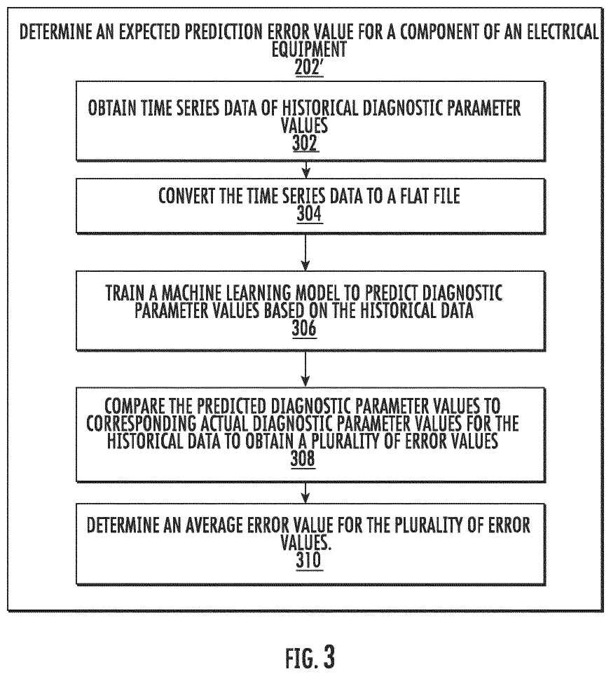

Referring now to FIG. 2B, a more detailed example of operations 200′ for determining a state of electrical equipment based on prediction error for predicted diagnostic parameter values for the electrical equipment is illustrated, according to some embodiments. In discussing the individual operations 200′ of FIG. 2B, reference will also be made to FIGS. 3-12B, which illustrate additional operations and examples of these and other features.

The operations 200′ of FIG. 2B may include determining an expected prediction error value for a component of an electrical equipment (Block 202′). Determining the expected prediction error value can be accomplished in several ways. For example, in some embodiments, a machine learning model may be trained to predict diagnostic parameter values for a normally functioning component, which can be compared to actual diagnostic parameter values to determine an expected, e.g., “baseline”, prediction error value.

In this regard, FIG. 3 illustrates additional operations for determining an expected prediction error value as part of the operations 200′ of FIG. 2B. The additional operations may include obtaining time series data of historical diagnostic parameter values (Block 302), and converting the time series data to a flat file (Block 304).

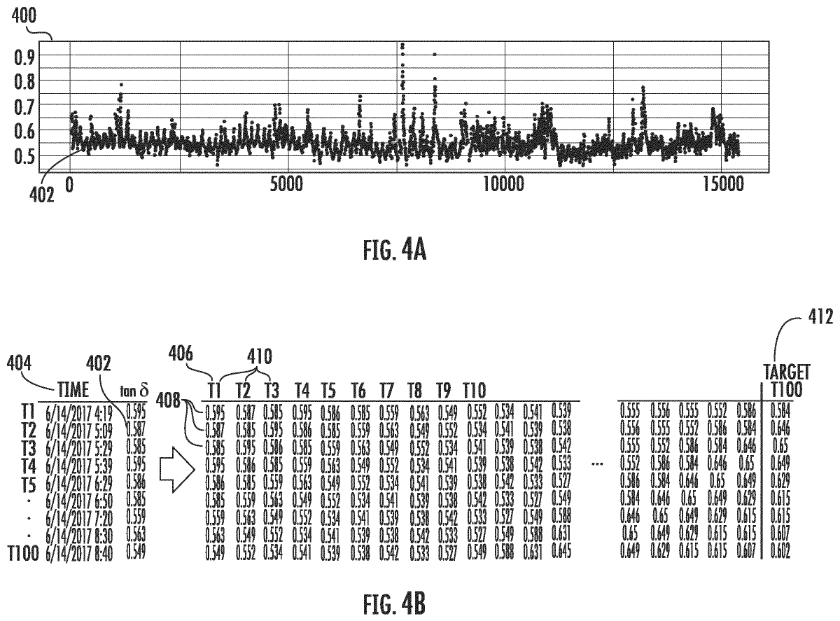

For example, FIG. 4A is a graphical plot 400 of historical power factor data 402 for a high voltage transformer bushing. As shown by FIG. 4A, a time series data stream 404 of the historical power factor data 402 is converted to a flat file 406, e.g., a regression model flat table in this example, with a plurality of rows 408 and column 410, with each row 408 corresponding to a sequence (e.g., a “moving window”) of consecutive diagnostic parameter values within the historical power factor data 402.

Referring back to FIG. 3, the additional operations may further include training a machine learning model to predict diagnostic parameter values based on the historical data (Block 306). For example, the flat file 406 of FIG. 4B can be used by the machine learning model to iteratively apply multivariate regression algorithms to each of the rows 408 of flat file 406, with the final column 412 as a target output for inputs based on the preceding columns, to determine and refine the algorithm over time. It should be understood, however, that the choice of the number of variables (i.e., predictors) will depend on each individual problem. The number of variables in each row 408 can be determined and optimized based on additional testing, e.g., for sensitivity, model accuracy, hardware and software constraints, and other parameters.

One advantage of this data transformation technique of FIG. 4B is the conversion of a single variable dataset (e.g., tan δ against time) into a multivariate problem, which facilitates the use of many machine learning models suitable for regression or classification applications. The power of such machine learning models is in the fact that they can “learn” from large datasets containing a large number of cases (or examples) and also a large number of features (or predictors, or independent variables).

One advantage of using these and other prediction techniques with diagnostic parameter data is that these techniques can provide very high accurate prediction of future diagnostic parameter values based on relatively small single variable datasets of historical diagnostic parameter values over time, without the need for any other external parameters such as temperature, holidays, events, etc. Moreover, the contributions of many of the variations introduced by external ambient conditions may be suppressed by application of these and other prediction techniques, thereby providing a more accurate indication of the actual state of the electrical equipment.

In some embodiments, many different machine learning models (e.g., linear and nonlinear algorithms) are trained using the flattened data, and the results are compared to determine the machine learning model with the highest accuracy. Many different criteria may be used to determine accuracy, such as root mean square error (RMSE), Mean Absolute Error (MAE), etc. Examples of suitable linear machine learning models may include general linear regression, logistic regression (e.g., for classification), linear discriminant analysis, etc. Examples of suitable non-linear machine learning models may include classification and regression trees, naïve-Bayesian, K-nearest neighbor, support vector machines, etc. Examples of suitable ensemble machine learning models may include random forest, tree-bagging, extreme gradient boosting machine, artificial neural networks, etc.

The predicted diagnostic parameter values can be predicted using machine learning models, statistical models, or any other suitable technique. For example, supervised or unsupervised machine learning model, such as a neural networks, may be used to recognize underlying relationships in a set of data to more accurately predict future values. In another example, a statistical model such as Auto-Regressive Integrated Moving Average (“ARIMA”), can account for and learn from past values in a time series, which in turn leads to more accurate predictions of future values. It should be understood, however, that any number of prediction techniques may be used, and disclosed embodiments are not limited to the above examples. In many embodiments, an increase in accuracy of the prediction of the diagnostic parameter values may result in a more reliable expected prediction error value, which in turn may increase the diagnostic value of an unexpected increase in prediction error. However, it should be understood that any technique that allows for prediction of diagnostic prediction values of electrical equipment may be used with embodiments described herein.

Referring back to FIG. 3, the predicted diagnostic values are next compared to the corresponding actual diagnostic parameter values for the historical data (Block 308) to obtain a plurality of error values for the electrical equipment. In this example, the predicted diagnostic values correspond to specific instants of time during the predetermined time period, and the corresponding actual diagnostic parameter values correspond to the same respective instants of time. In this example, an average error value is determined for the plurality of error values (Block 310), which can be used as the expected prediction error value for subsequent measurements and comparisons.

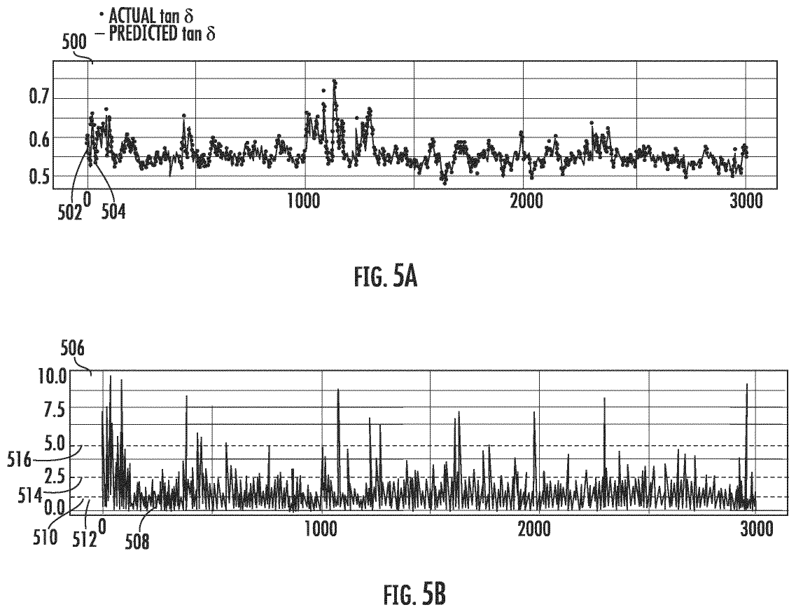

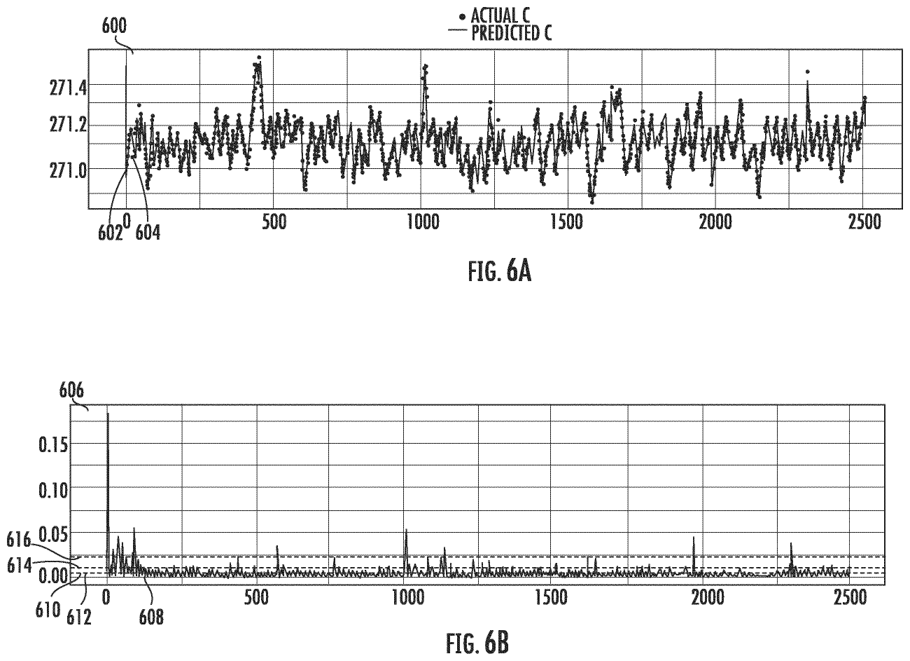

In this manner, the machine learning model or other suitable prediction technique can be used to determine expected prediction error values for a number of diagnostic parameters. Examples of determining an expected prediction error value for historical power factor data (FIGS. 5A-5B) and historical capacitance data (FIGS. 6A-6B) will now be described below.

Referring now to FIG. 5A, a graphical plot 500 illustrates a plurality of predicted power factors 502 and actual power factors 504 over a period of time for a transformer bushing that is functioning normally. As discussed above, the predicted power factors 502 can be predicted using a supervised or unsupervised machine learning model such as a neural network, a statistical model such as Auto-Regressive Integrated Moving Average (“ARIMA”), or other suitable technique for predicting power factors or other diagnostic parameter values. The actual power factors 504 are measured or derived from measurements of the transformer bushing for the corresponding time period.

As shown by FIG. 5B, the comparison of the predicted power factors 502 to the actual power factors 504 produces a graphical plot 506 of a plurality of error values 508 for the normally functioning transformer bushing. The mean prediction error 510 for the plurality of error values 508 in this example is 0.98%, which can be used as an expected prediction error value 512 for comparison against future power factor prediction error determinations for transformer bushings in active use. In some embodiments, a different value may be used as the expected prediction error value, such as a 95th percentile value 514 (i.e., a maximum value of the error values 508 that excludes the largest 5% of error values 508), 99th percentile value 516, etc.

These techniques can be used to determine an expected prediction error value for other diagnostic parameters as well, such as capacitive current, dissipation factor, and/or power factor, etc. In this regard, FIG. 6A is a graphical plot 600 illustrating comparisons of predicted capacitances 602 and actual capacitances 604 for a transformer bushing over a period of time. FIG. 6B is a graphical plot 606 of a plurality of error values 608 produced by the comparison of the predicted capacitances 602 to the actual capacitances 604 of for the normally functioning transformer bushing. The mean prediction error 610 for the plurality of error values 608 in this example is 0.0043%, which can be used as an expected prediction error value 612 for comparison against future capacitance prediction error determinations for transformer bushings in active use. As noted above, different values may also be used, such as a 95th percentile value 614, 99th percentile value 616, etc., as desired.

Referring back to FIG. 2B, the operations 200′ may further include predicting a plurality of predicted diagnostic parameter values over a predetermined time period (Block 204′), for example, with the trained machine learning model described above. The operations 200′ may further include obtaining a plurality of actual diagnostic parameter values for the predetermined time period (Block 206′), which can be measured or derived from measurements of the transformer bushing for the corresponding time period, for example.

The operations 200′ may further include determining a prediction error value for the plurality of predicted diagnostic parameter values (Block 208′), for example, by comparing the predicted diagnostic parameter values to the actual diagnostic parameter values. In this regard, FIG. 7 illustrates additional operations for determining a prediction error value as part of the operations of FIG. 2B, according to some embodiments.

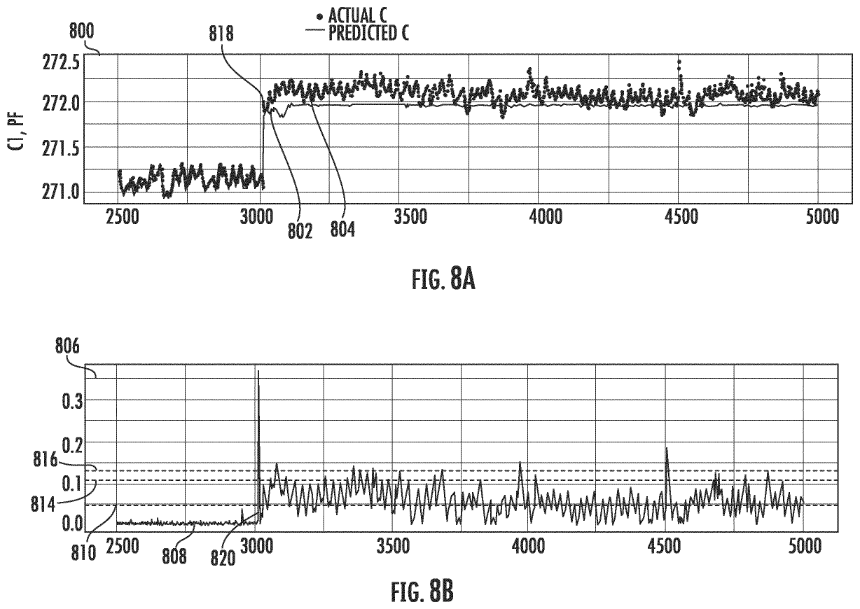

The additional operations of FIG. 7 may further include predicting a plurality of diagnostic parameter values using the machine learning model (Block 702), or other suitable prediction technique. A corresponding plurality of actual diagnostic parameter values is also obtained (Block 704). In this regard, FIG. 8A is a graphical plot 800 illustrating predicted capacitances 802 and actual capacitances 804 over time for a transformer bushing in the field. In this example, the predicted diagnostic values correspond to specific instants of time during the predetermined time period, and the corresponding actual diagnostic parameter values correspond to the same respective instants of time. In this example, the trained machine learning model used for determining the predicted capacitances 602 for the normally functioning transformer bushing of FIG. 6A is also used to predict the predicted capacitances 802 of the transformer bushing in the field of FIG. 8A. For this example, a relatively small, but sudden increase 818 in the actual capacitances 804 (e.g., 1 pF) occurs at time T.

The additional operations of FIG. 7 may further include comparing the predicted diagnostic parameter values to the obtained actual diagnostic parameter values to determine a plurality of error values. In this regard, FIG. 8B is a graphical plot 806 of a plurality of error values 808 produced by comparison of the predicted capacitances 802 to the actual capacitances 804 shown in FIG. 8A for the transformer bushing in the field. Due to the sudden increase 818 in the actual capacitances 804 shown in FIG. 8A, the error values 808 also show a large, sustained increase 820 at time T.

The additional operations of FIG. 7 may further include determining an average error value for the plurality of error values (Block 708). For example, as shown in FIG. 8B, the mean prediction error 810 for the plurality of error values 808 in this example is 0.0435%, as a result of that sharp increase 820 in the error values 808. In this manner, the mean prediction error 810 is indicative of a deviation of an observed behavior, i.e., the sudden increase 818 in the actual capacitances 804, from an expected behavior, i.e., the predicted capacitances 802. As noted above, different values may also be used, such as a 95th percentile value 814, 99th percentile value 816, etc., as desired.

Referring back to FIG. 2B, the operations 200′ may further include comparing the determined prediction error value to the expected prediction error value (Block 210′). For example, the mean prediction error 810 (i.e., average error value) of FIG. 8B can be compared to the expected prediction error value 612 that was determined in FIG. 6B for the normally functioning transformer bushing. In this example, the mean prediction error 810 of 0.0435% is approximately ten times the expected prediction error value 612 of 0.0043%, despite the relatively small size of the capacitance increase 818 in absolute terms. This represents a clear and easily detected indication of anomalous behavior (i.e., a sudden increase in capacitance) by the transformer bushing in the field. In this and other examples, a significant deviation in the actual diagnostic parameter values may result in a corresponding increase in the prediction error that can be detected and monitored.

In this regard, referring back to FIG. 2B, the operations 200′ may further include selectively generating an indication of a state of the at least one component based on the comparison (Block 212′). In some embodiments for example, a prediction error threshold can be determined based on the expected prediction error value, and an alert indication can be selectively generated in response to determining that the prediction error value meets the predetermined prediction error threshold. Alternatively, or in addition, an indication can also be selectively generated in response to response to the prediction error value failing to meet the predetermined prediction error threshold.

In some examples, the prediction error threshold can be a specific value or a range of values. The indication(s) may also include an indication of a specific value or range of values, a classification type, e.g., “good or bad”, “yes or no”, levels 1,2,3, etc., or any other appropriate indication, as desired.

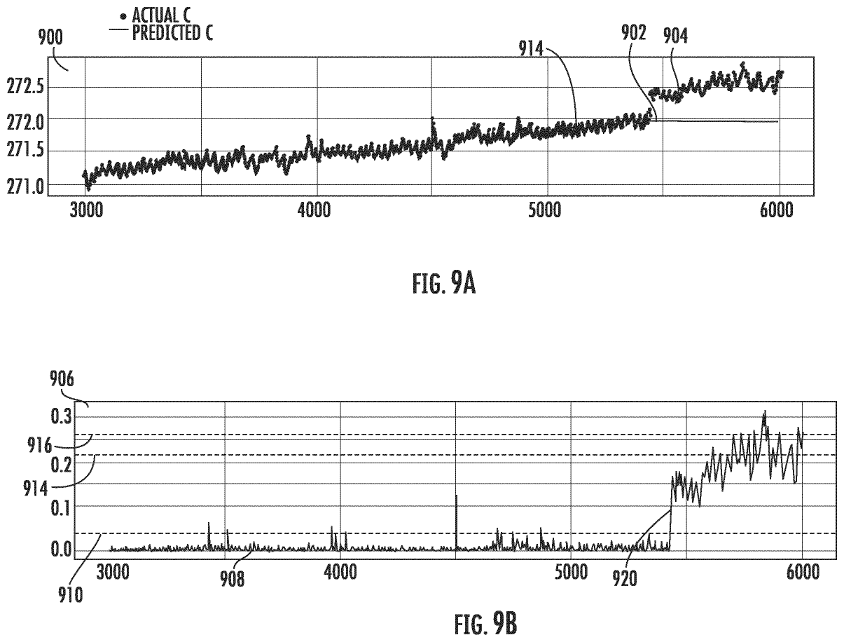

Embodiments disclosed herein are capable of detecting and indicating other types of anomalous behavior as well. For example, FIG. 9A is a graphical plot 900 illustrating comparisons of predicted capacitances 902 and actual capacitances 904 for a transformer bushing where the actual capacitance exhibits a linear increase 918 over time. As shown by FIG. 9B, this relatively small linear increase 918 in capacitance (e.g., 3 pF) results in a measurable increase 920 in corresponding error values 908 as well, which results in a mean prediction error 910 of 0.0408%, more than nine times the expected prediction error value 612 of 0.0043% (shown in FIG. 6B). As noted above, different values may also be used, such as a 95th percentile value 914, 99th percentile value 916, etc., as desired.

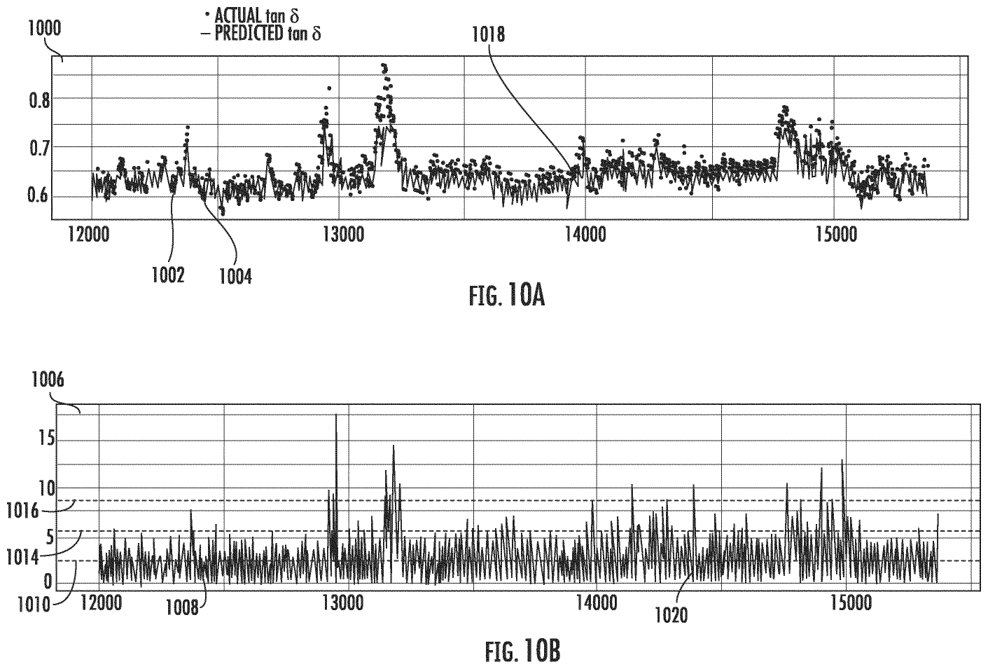

In another example, FIG. 10A is a graphical plot 1000 illustrating comparisons of predicted power factors 1002 and actual power factors 1004 over time for a transformer bushing in the field, where the actual power factors 1004 exhibits a linear increase 1018 over time. Here again, this linear increase 1018 in capacitance results in a measurable increase 1020 in corresponding error values 1008 as well, as shown by FIG. 10B, which results in a mean prediction error 1010 of 2.36%, much higher than the expected prediction error value 512 of 0.98% (shown in FIG. 5B). As noted above, different values may also be used, such as a 95th percentile value 1014, 99th percentile value 1016, etc., as desired.

As discussed above, variations in the observed behavior of the transformer bushing (or other component) can detected and/or suppressed in a number of ways. For example, as discussed above with respect to the machine learning model examples disclosed herein, the prediction technique itself may suppress many of the variations introduced by external ambient conditions. For example, the prediction technique may be trained or configured to distinguish between variations due to ambient conditions and normal ageing of a component, i.e., “healthy” variations, and variations due to underlying issues with the component, such as damage, excess wear, or other undesirable variations. Alternatively, or in addition, variations can also be suppressed by obtaining average values for sets of diagnostic parameter values over time.

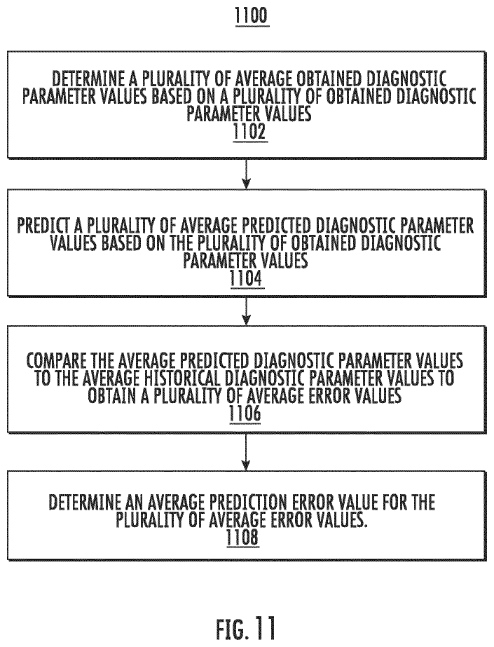

Referring now to FIG. 11, operations 1100 for determining prediction error based on average predicted diagnostic parameter values and average obtained prediction error values, according to some embodiments. These operations 1100 may be used as part of the operations 200′ of FIG. 2B, for example, such as determining the expected prediction error value (Block 202′), and/or determining the prediction error value for the plurality of predicted diagnostic parameter values (Block 208′), etc.

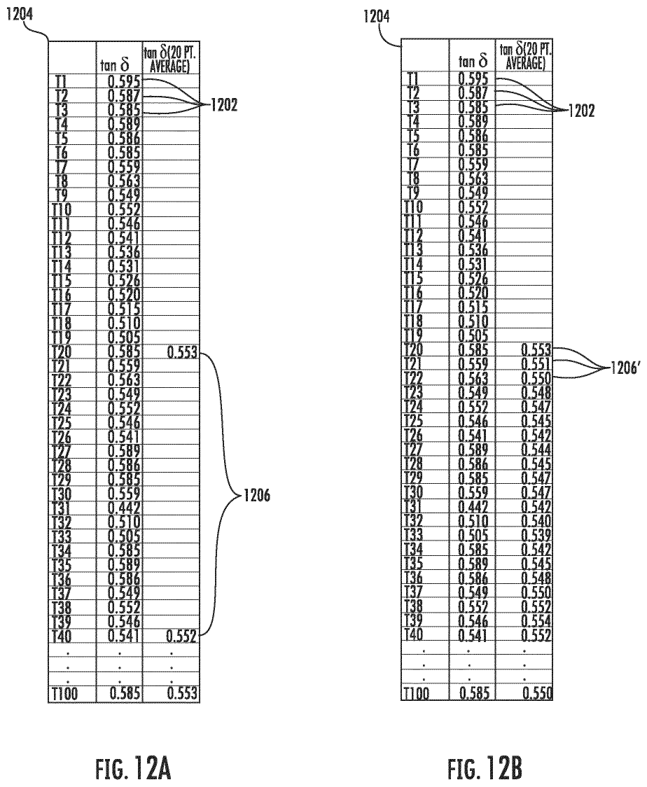

The operations 1100 of FIG. 11 may include determining a plurality of average obtained diagnostic parameter values based on a plurality of obtained diagnostic parameter values (Block 1102). For example, FIGS. 12A and 12B illustrate calculation of a plurality of average values (i.e., a moving average) from a time series data stream 1204 of a diagnostic parameter value, according to some embodiments. In FIG. 12A, power factor values 1202 are obtained from a time series data stream 1204, which may exhibit variations over time due to ambient conditions, such as environmental factors, temperature, etc. The power factor values 1202 are converted to a plurality of average power factor values 1206, which further reduces the effect of ambient variations on the measured values. In this example, each set of twenty obtained power factor values 1202 is averaged to produce a single average power factor value 1206.

In some examples, a sufficiently large set of obtained diagnostic parameter values can produce a usable set of average diagnostic parameter values (e.g., 100 values associated with 100 instants of time, for example) using the technique of FIG. 12A. Alternatively, or in addition, it may be desirable to determine an average value for each obtained diagnostic parameter value, to obtain a larger set of data points for use by the machine learning model, statistical model, or other prediction technique. In this regard, FIG. 12B illustrates conversion of the power factor values 1202 obtained from a time series data stream 1204 into a plurality of average power factor values 1206′, with each average power factor value based on the obtained power factor value and the previous nineteen obtained power factor values in the sequence. In this manner, each average power factor value 1206′ may still suppress variations in the obtained power factor values 1202, but with a much larger number of average power factor values 1206′ for use by the prediction technique, thereby increasing the overall accuracy of the prediction technique.

The operations 1100 of FIG. 11 may further include predicting a plurality of average predicted diagnostic parameter values based on the plurality of obtained diagnostic parameter values (Block 1104). For example, a plurality of predicted diagnostic parameter values may be determined using the machine learning model or other prediction techniques described above. A plurality of average predicted diagnostic parameter values may then be determined based on the plurality of predicted diagnostic parameter value, using the same or similar processes of FIGS. 12A and/or 12B, for example.

The operations 1100 of FIG. 11 may further include comparing the average predicted diagnostic parameter values to the average historical diagnostic parameter values to obtain a plurality of average error values (Block 1106), and determining an average prediction error value for the plurality of average error values (Block 1108), similar to the techniques described above with respect to FIGS. 3 and 7 et al.

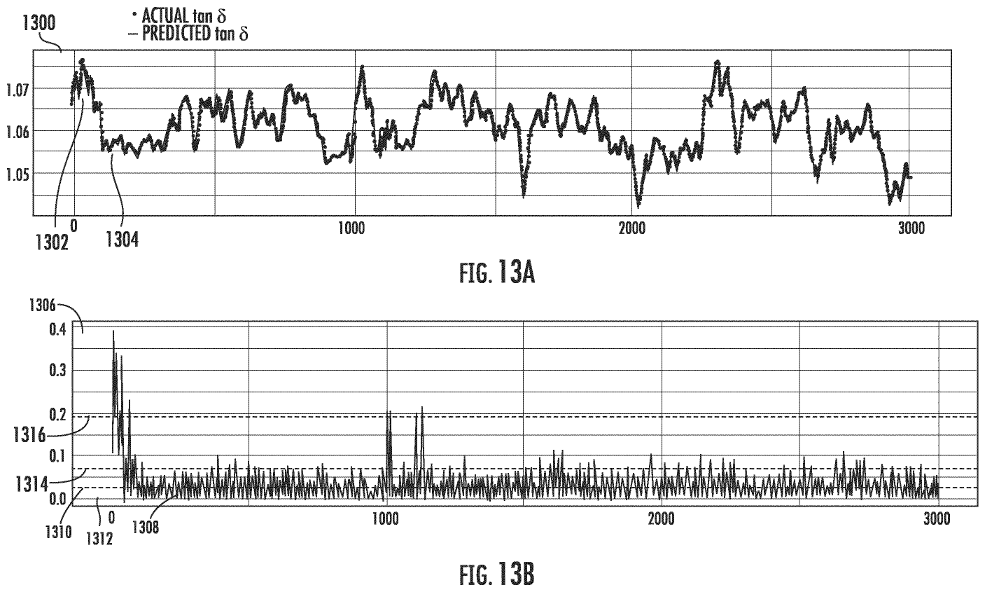

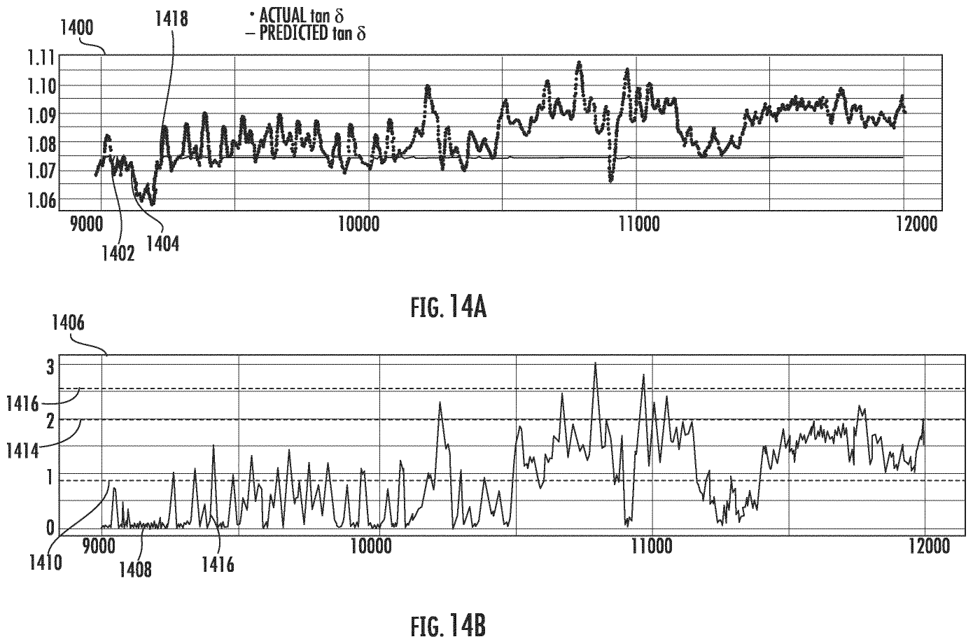

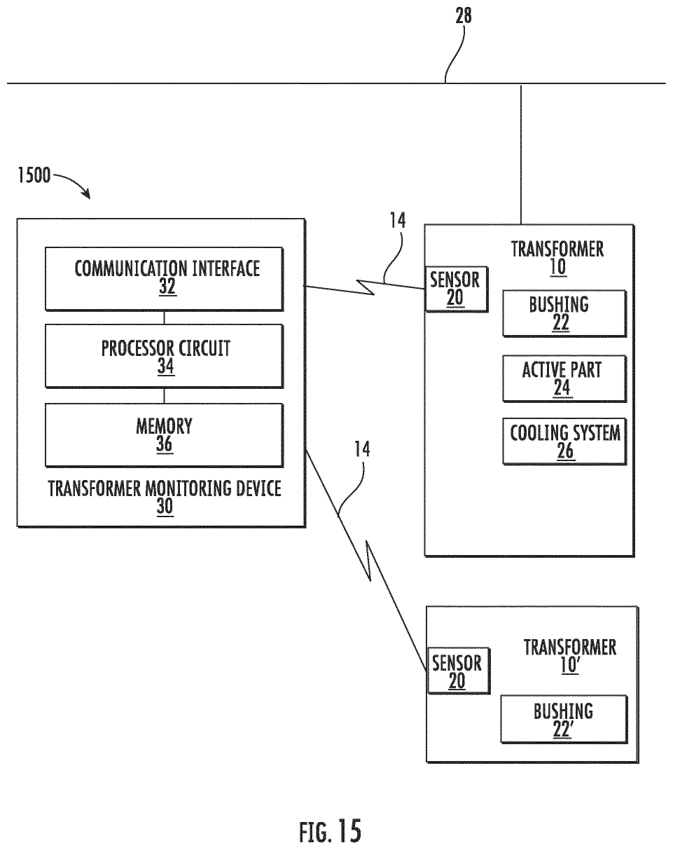

A further application of the operations 1100 of FIG. 11 is illustrated by the example of FIGS. 13A-14B. FIG. 13A is a graphical plot 1300 illustrating comparisons of a plurality of average predicted power factors 1302 and a plurality of average actual power factors 1304 over time for a normally functioning transformer bushing. In this embodiment, each average predicted power factor data point 1318 represents an average of 100 predicted power factor samples (see Block 1104 of FIG. 11), and each average actual power factor data point 1320 represents an average of 100 corresponding actual power factor samples (see Block 1102 of FIG. 11). As shown by the graphical plot 1306 of FIG. 13B, average error values 1308 are obtained from comparisons of the plurality of average predicted power factors 1302 with the plurality of average actual power factors 1304 (see Block 1106 of FIG. 11). For example, as with the examples above, a mean prediction error 1310 in FIG. 13B is calculated for the plurality of average error values 1308 (see Block 1108 of FIG. 11). In this example, the mean prediction error 1310 is 0.03%, which can be used as an expected prediction error value 1312 for comparison against future prediction error determinations for transformer bushings in active use (see, e.g., FIG. 3). As noted above, different values may also be used, such as a 95th percentile value 1314, 99th percentile value 1316, etc., as desired. In this example, by averaging groups of predicted and actual power factor samples prior to determining the average error values 1308, variations in the observed behavior of the transformer bushing are further suppressed, and the expected prediction error in this example is reduced from 0.98% (see FIG. 5B, which does not employ the moving average technique of this example) to 0.03% in this example. This reduction in the expected prediction error value 1312, i.e., baseline value, increases the likelihood of detecting increases in prediction error when monitoring equipment in the field, thereby increasing the likelihood of detecting anomalous behavior in the equipment.

Similar moving average techniques can be used for predicting diagnostic parameter values and determining prediction error values for equipment in the field (see, e.g., FIG. 7). In this regard, FIG. 14A is a graphical plot 1400 illustrating comparisons of a plurality of average predicted power factors 1402 and a plurality of average actual power factors 1404 over time for a transformer bushing in the field. In this example, the trained machine learning model used for determining the average predicted power factors 1302 for the normally functioning transformer bushing of FIG. 13A is also used to predict the plurality of average predicted power factors 1402 of the transformer bushing in the field of FIG. 14A. For this example, the plurality of average actual power factors 1404 exhibits a linear increase 1414 over time. As shown by the graphical plot 1406 FIG. 14B, this linear increase 1414 in the average actual power factors 1404 results in a measurable increase 1416 in corresponding error values 1408 as well, which results in a mean prediction error value 1410 of 0.9%, approximately thirty times the expected prediction error value 1312 of 0.03% (shown in FIG. 14B). As noted above, different values may also be used, such as a 95th percentile value 1414, 99th percentile value 1416, etc., as desired.

As discussed above, while many of the above embodiments relate to determining a state of insulation components (e.g., high voltage bushings), based on diagnostic parameters relating to capacitance, power factor, etc., it should be understood that the embodiments disclosed herein have a wide range of applications. For example, many of the same ambient conditions that affect capacitance-based diagnostic parameters may also affect diagnostic parameters for detecting and measuring other aspects of transformer and other electrical equipment, such as partial discharge (PD), oil temperature, and/or Dissolved Gas Analysis (DGA), for example. Other types of electrical equipment that can benefit from embodiments disclosed herein may include circuit breakers to monitor condition of the contacts (i.e., physical wear), gas leaks, operating mechanisms (e.g., travel time), etc.

For example, diagnostic parameters related to breaker travel time monitoring may include force experienced by the circuit breaker contact, which may be affected by a number of ambient conditions, such as arcing, insulation gas properties (e.g., gas electronegativity, gas mixture), load current, instant of switching, temperature around contacts, space charges in sulfur hexafluoride or other cooling gasses, instantaneous potential difference between contacts, load current, type of loads (e.g., impedance), etc. With sufficient volumes of historical data for these different diagnostic parameters, these and other prediction techniques can be trained or configured to detect component states and deviations from expected states irrespective of the extent or effect of ambient conditions on the measured data.

Referring now to FIG. 15, a block diagram of a transformer monitoring system 1500 is illustrated. The transformer monitoring system 1500 in this example is configured to perform operations according to some embodiments, such as the operations of FIGS. 2, 3, 7, and/or 11, et al. A transformer monitoring device 30 of the transformer monitoring system 1500 can monitor one or multiple transformers 10A, 10B. In some embodiments, the transformer monitoring device 30 is integrated within a transformer 10A provided as a device and can be enabled to monitoring only the transformer 10A, while in other embodiments, the transformer monitoring device 30 can be integrated with the transformer 10A to monitor the transformer 10A and optionally also monitor or receive data from a neighboring one or more electrical equipment (e.g. transformer 10B or another power or current transformer or circuit breaker) or connected transmission/distribution line. In yet another embodiment, the transformer monitoring device 30 is separate from the transformers 10A, 10B being monitored.

The transformer monitoring device 30 includes a processor circuit 34, a communication interface 32 coupled to the processor circuit, and a memory 36 coupled to the processor circuit 34. The memory 36 includes machine-readable computer program instructions that, when executed by the processor circuit 34, cause the processor circuit 34 to perform some of the operations depicted and described herein, such as operations of FIGS. 2, 3, 7, and/or 11, for example.

As shown, the transformer monitoring system 1500 includes a communication interface 32 (also referred to as a network interface) configured to provide communications with other devices, e.g., with sensors 20 in the transformers 10A, 10B via a wired or wireless communication channel 14. The transformer monitoring device 30 may receive signals from the sensors 20 indicative of diagnostic parameters of the transformers 10A, 10B, e.g., voltage, current, oil temperature, ambient temperature, etc., associated with the transformers 10A, 10B.

In this example, the transformer monitoring device 30 is depicted as a separate monitoring device that communicates with the transformers 10A, 10B circuit via communication channels 14, e.g., in a server-client model, cloud-based platform, a substation automation system used in a substation, a distribution management system used for power system management, or other network arrangements. One advantage of a client-server configuration is that monitoring and prediction of diagnostic parameters can be obtained for a plurality of individual equipment, such as transformers 10A, 10B. For example, diagnosis of a problem with one electrical equipment in a power system may include redistributing loads across different electrical equipment, based on the determined states of the different electrical equipment. However, it should also be understood that, in other embodiments, the transformer monitoring device 30 may be part of the transformer 10A, 10B or other electrical equipment as desired.

In another embodiment of the server-client model, the transformer monitoring system can have a device (e.g., client) associated with the transformer being monitored, wherein the device comprises a machine learning model, statistical model, or other prediction tool, and a central system (e.g., server) is configured to monitor multiple electrical equipment/transformers. The server may also include an instance of the machine learning model or other prediction tool comprised in the device associated with the transformer. The machine learning model or other prediction tool in the server may be continuously trained, tuned, adapted, etc. with data received from the transformer or/and the multiple electrical equipment, with the server providing information/data for tuning/adapting the prediction tool in the server. The server may also be capable of performing simulation or advanced processing to forecast/simulate conditions in the transformer (e.g. failure or degradation of a transformer bushing based on capacitance and/or power factor data made available by the device or sensors connected to the transformer) and to provide information relating to such determination to the device (e.g., client) connected to the transformer to change at least one parameter (e.g. cooling, output, online status) associated with the transformer (or other electrical equipment) by the device. According to various embodiments, the transformer monitoring device 30 may include electronic, computing and communication hardware and software for measuring and predicting diagnostic parameter values and performing at least one activity associated with the transformer.

The transformer monitoring device 30 also includes a processor circuit 34 (also referred to as a processor) and a memory circuit 36 (also referred to as memory) coupled to the processor circuit 34. According to other embodiments, a separate memory may be omitted and the processor circuit 34 may be defined to include memory.

As discussed herein, operations of transformer monitoring device 30 and other aspects of the transformer monitoring system 1500 may be performed by processor circuit 34 and/or communication interface 32. For example, the processor circuit 34 may control the communication interface 32 to transmit communications through the communication interface 32 to one or more other devices and/or to receive communications through network interface from one or more other devices. Moreover, modules may be stored in memory 36, and these modules may provide instructions so that when instructions of a module are executed by processor circuit 34, processor circuit 34 performs respective operations (e.g., operations discussed herein with respect to example embodiments). For example, modules may be further configured to obtain diagnostic parameter values, predict diagnostic parameter values, determine prediction error values, and determine states and/or conditions of components of the electrical equipment.

The transformer 10, which may for example be a high voltage transformer, includes a sensor 20 that measures various quantities associated with the transformer 10A, 10B such as voltage, current, operating load, ambient temperature, moisture and/or oxygen content for various components of the transformer 10, and transmits the measurements via communication channel 14 to the transformer monitoring device 30. For example, the sensor 30 may be configured in this example to obtain measurements associated with a bushing 22 or other insulation component of the transformer 10. The transformer 10 may also include sub-systems, such as an active part 24 coupled to a power line 28 (e.g., an overhead power transmission line), cooling system 26 (e.g., for a transformer or reactor), etc., which may in turn be operated by or in response to instructions from the processor circuit 34 for example.

In this and other examples, embodiments are described in a context of transformers for simplicity of illustration, but it should be understood that many other types of electrical equipment and components thereof may benefit from the embodiments described herein, such as reactors, transmission lines, instrument transformers, generators etc., and all such electrical equipment should also be contemplated as being within the scope of the present disclosure.

These measured quantities can be used by the transformer monitoring device 30 to detect and/or determine the presence of faults in various components or subsystems of the transformer 10A, 10B, and/or a general fault condition of the transformer 10. The communication channel 14 may include a wired or wireless link, and in some embodiments may include a wireless local area network (WLAN) or cellular communication network, such as a 4G or 5G communication network.

The transformer monitoring system 1500 may receive on-line or off-line measurements of voltage, current, operating load, temperature, moisture, oxygen content, etc. from the transformer 10A, 10B and process the measurements to perform the operations described herein. The transformer monitoring system 1500 may be implemented in a server, in a server cluster, a cloud-based remote server system, and/or a standalone device. Sensor data may be obtained by the transformer monitoring system 1500 from one transformer and/or from multiple transformers.

A transformer monitoring system 1500 as described herein may be implemented in many different ways. For example, a transformer monitoring system 1500 according to some embodiments may receive online/offline data, and the received data used by a machine learning or other prediction technique described in various embodiments. The device may be connectable to one or more transformers 10 to receive diagnostic parameter values and/or other types of measurement data.

In the above description of various embodiments of the present disclosure, it is to be understood that the terminology used herein is for the purpose of describing particular embodiments only and is not intended to be limiting of the present disclosure. Unless otherwise defined, all terms (including technical and scientific terms) used herein have the same meaning as commonly understood by one of ordinary skill in the art to which the present disclosure belong. It will be further understood that terms, such as those defined in commonly used dictionaries, should be interpreted as having a meaning that is consistent with their meaning in the context of this specification and the relevant art.

When an element is referred to as being “connected”, “coupled”, “responsive”, or variants thereof to another element, it can be directly connected, coupled, or responsive to the other element or intervening elements may be present. In contrast, when an element is referred to as being “directly connected”, “directly coupled”, “directly responsive”, or variants thereof to another element, there are no intervening elements present. Like numbers refer to like elements throughout. Furthermore, “coupled”, “connected”, “responsive”, or variants thereof as used herein may include wirelessly coupled, connected, or responsive. As used herein, the singular forms “a”, “an” and “the” are intended to include the plural forms as well, unless the context clearly indicates otherwise. Well-known functions or constructions may not be described in detail for brevity and/or clarity. The term “and/or” includes any and all combinations of one or more of the associated listed items. The phrase “at least one of A and B” means “A or B” or “A and B”.

It will be understood that although the terms first, second, third, etc. may be used herein to describe various elements/operations, these elements/operations should not be limited by these terms. These terms are only used to distinguish one element/operation from another element/operation. Thus, a first element/operation in some embodiments could be termed a second element/operation in other embodiments without departing from the teachings of the present disclosure. The same reference numerals or the same reference designators denote the same or similar elements throughout the specification.

As used herein, the terms “comprise”, “comprising”, “comprises”, “include”, “including”, “includes”, “have”, “has”, “having”, or variants thereof are open-ended, and include one or more stated features, integers, elements, steps, components, or functions but does not preclude the presence or addition of one or more other features, integers, elements, steps, components, functions, or groups thereof.

Example embodiments are described herein with reference to block diagrams and/or flowchart illustrations of computer-implemented methods, apparatus (systems and/or devices) and/or computer program products. It is understood that a block of the block diagrams and/or flowchart illustrations, and combinations of blocks in the block diagrams and/or flowchart illustrations, can be implemented by computer program instructions that are performed by one or more computer circuits. These computer program instructions may be provided to a processor circuit of a general purpose computer circuit, special purpose computer circuit, and/or other programmable data processing circuit to produce a machine, such that the instructions, which execute via the processor of the computer and/or other programmable data processing apparatus, transform and control transistors, values stored in memory locations, and other hardware components within such circuitry to implement the functions/acts specified in the block diagrams and/or flowchart block or blocks, and thereby create means (functionality) and/or structure for implementing the functions/acts specified in the block diagrams and/or flowchart block(s).

These computer program instructions may also be stored in a tangible computer-readable medium that can direct a computer or other programmable data processing apparatus to function in a particular manner, such that the instructions stored in the computer-readable medium produce an article of manufacture including instructions which implement the functions/acts specified in the block diagrams and/or flowchart block or blocks. Accordingly, embodiments of the present disclosure may be embodied in hardware and/or in software (including firmware, resident software, micro-code, etc.) that runs on a processor such as a digital signal processor, which may collectively be referred to as “circuitry,” “a module” or variants thereof.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the disclosure. Moreover, although some of the diagrams include arrows on communication paths to show a primary direction of communication, it is to be understood that communication may occur in the opposite direction to the depicted arrows.

Many variations and modifications can be made to the embodiments without substantially departing from the principles of the present disclosure. All such variations and modifications are intended to be included herein within the scope of the present disclosure. Accordingly, the above disclosed subject matter is to be considered illustrative, and not restrictive, and the examples of embodiments are intended to cover all such modifications, enhancements, and other embodiments, which fall within the spirit and scope of the present disclosure. Thus, to the maximum extent allowed by law, the scope of the present disclosure is to be determined by the broadest permissible interpretation of the present disclosure including the examples of embodiments and their equivalents, and shall not be restricted or limited by the foregoing detailed description.

1. A method comprising:
determining, by a processor circuit, a prediction error value for a plurality of predicted diagnostic parameter values over a predetermined time period for at least one component of an electrical equipment, the prediction error value suppressing ambient variations observed in behavior of the at least one component;
comparing the determined prediction error value to an expected prediction error value; and
selectively generating, by the processor circuit, an indication of a state of the at least one component based on the comparison.

2. The method of claim 1, wherein the at least one component comprises an insulation component of the electrical equipment, and
wherein the plurality of predicted diagnostic parameter values comprise a plurality of predicted insulation diagnostic parameter values.

3. The method of claim 2, wherein the plurality of predicted insulation diagnostic parameter values comprises a plurality of at least one of predicted capacitance values, predicted capacitive current values, predicted dissipation factor values, and predicted power factor values of the at least one insulation component.

4. The method of claim 2, wherein the electrical equipment comprises a transformer, and
wherein the at least one component comprises a high voltage bushing of the transformer.

5. The method of claim 1, wherein the suppressed variations observed in the behavior of the at least one component comprise variations due to ambient conditions.

6. The method of claim 5, wherein the variations due to ambient conditions comprise variations due to at least one of environmental conditions, noise, vibration, and special cause variation.

7. The method of claim 1, wherein determining the prediction error value further comprises at least one of:
predicting, by the processor circuit, at least one error value for the plurality of predicted diagnostic parameter values;
determining a variation in the at least one error value due to ambient conditions observed in behavior of the at least one component; and
generating the prediction error value based on the at least one error value and the determined variation.

8. The method of claim 1, wherein determining the prediction error value further comprises:
predicting the plurality of predicted diagnostic parameter values for a plurality of respective instants of time of the predetermined time period based on obtained diagnostic parameter values; and
determining a plurality of error values based on comparisons of the plurality of predicted diagnostic parameter values for the respective instants of time with a plurality of actual diagnostic parameter values obtained at the respective instants of time, wherein the prediction error value comprises an average error value for the plurality of error values.

9. The method of claim 8, wherein the plurality of actual diagnostic parameter values is obtained from a parameter value data stream generated from a device associated with the at least one component.

10. The method of claim 8, wherein the plurality of instants of time comprises at least 100 instants of time of the predetermined time period.

11. The method of claim 1, wherein the plurality of predicted diagnostic parameter values is associated with an expected behavior of the at least one component, and
wherein the prediction error value is indicative of a deviation of an observed behavior of the at least one component from the expected behavior of the at least one component.

12. The method of claim 1, wherein the expected prediction error value is determined based on a comparison of a plurality of previously predicted diagnostic parameter values and a corresponding plurality of previously obtained diagnostic parameter values.

13. The method of claim 1, wherein the plurality of predicted diagnostic parameter values is determined based on a plurality of determined relationships between a predefined number of diagnostic parameter values of a plurality of previously obtained diagnostic parameter values and at least one subsequent parameter value of the plurality of previously obtained diagnostic parameter values.

14. The method of claim 13, wherein the plurality of previously obtained diagnostic parameter values is obtained from a different component from the at least one component.

15. The method of claim 1, wherein the plurality of predicted diagnostic parameter values is determined based on at least one of a machine learning model and a statistical model.

16. The method of claim 1, wherein the expected prediction error value is determined based on at least one of a machine learning model and a statistical model.

17. The method of claim 1, wherein selectively generating the indication further comprises:
determining, by the processor circuit, whether the prediction error value meets a predetermined prediction error threshold, the predetermined prediction error threshold based on the expected prediction error value; and
generating a first alert indication in response to the prediction error value meeting the predetermined prediction error threshold.

18. The method of claim 17, wherein selectively generating the indication further comprises generating a second alert indication in response to the prediction error value failing to meet the predetermined prediction error threshold.

19. An insulation diagnostic system comprising:
a processor circuit; and
a memory comprising machine-readable instructions that, when executed by the processor circuit, cause the processor circuit to:
determine a plurality of predicted diagnostic parameter values over a predetermined time period for at least one component of an electrical equipment;
obtain a plurality of actual diagnostic parameter values over a predetermined time period from the at least one component;
determine a prediction error value based on the plurality of predicted diagnostic parameter values and the plurality of actual parameter values, the prediction error value suppressing ambient variations observed in behavior of the at least one component;
compare the determined prediction error value to an expected prediction error value; and
selectively transmit an indication of a state of the at least one component to the electrical equipment based on the comparison.

20. The system of claim 19, wherein the at least one component comprises an insulation component of the electrical equipment,
wherein the plurality of predicted diagnostic parameter values comprise a plurality of predicted insulation diagnostic parameter values, and
wherein the plurality of actual diagnostic parameter values comprise a plurality of actual insulation diagnostic parameter values.

21. (canceled)

22. (canceled)
